(19) United States
(12) Patent Application Publication
(10) Pub. No.: US 2004/0029380 A1
(43) Pub. Date: Feb. 12, 2004

(54) Method for forming a capping layer on a copper interconnect

(75) Inventor: Koichi Ohto, Tokyo (JP)

Correspondence Address: YOUNG & THOMPSON, 745 SOUTH 23RD STREET 2ND FLOOR, ARLINGTON, VA, 22202

(73) Assignee: NEC ELECTRONICS CORPORATION, KANAGAWA (JP)

(21) Appl. No.: 10/622,645

(22) Filed: Jul. 21, 2003

Related U.S. Application Data
(62) Division of application No. 10/212,234, filed on Aug. 6, 2002.
Application No. 10/212,234 is a division of application No. 09/727,675, filed on Dec. 4, 2000, now abandoned.

(30) Foreign Application Priority Data
Dec. 2, 1999 (JP) 11-343510

(51) Int. Cl. H01L 21/44

(52) U.S. Cl. 438/687

(57) ABSTRACT

A method for fabricating a semiconductor device wherein an interconnect made of copper overlying a substrate is pretreated at a specified temperature, for example, at 300° C. or less; and a dielectric film is formed on the copper at a temperature higher than that of the pretreatment. In accordance with the present invention, the adhesion between the copper and the dielectric film is improved by conducting the pretreatment of the dielectric film for reducing an oxide layer of the copper surface, and the agglomeration of the copper can be prevented by the pretreatment.

### BACKGROUND OF THE INVENTION

(a) Field of the Invention

The present invention relates to a method for fabricating a semiconductor device and an apparatus for fabricating the same, more in particular to formation of an interlayer dielectric film during the fabrication of the semiconductor device.

(b) Description of the Related Art

In the fabrication of integrated circuits, a device having smaller dimensions is designed for achieving a high speed operation and a higher integration of the device. The reduction of the interconnect size and the interconnect pitch caused by the reduction of the device dimensions may increase the interconnect resistance and the parasitic capacitance between the interconnects, that increases the RC time constant. The reduction of the propagation speed due to the increase of the RC time constant is the critical problem in performing the high speed operation of the device. The parasitic capacitance increases proportional to the area of the interconnect and to the dielectric constant of the interlayer dielectric film and inversely proportional to the distance between the adjacent interconnects. The reduction of the dielectric constant of the interlayer dielectric film is most effective for reducing the parasitic capacitance without changing the device design. The various interlayer dielectric layers are examined such as SiOF having a dielectric constant lower than those of the conventional interlayer dielectric layers such as SiO₂. On the other hand, in order to reduce the interconnect resistance, the technique using, as an interconnect material, copper having a specific resistance lower than that of aluminum conventionally used has been developed and used in commercial products.

In a damascenel method widely used for forming the interconnect by using the copper as the interconnect material, trenches formed in the interlayer dielectric film are filled with a barrier metal and the copper, and the surplus copper and the surplus barrier metal on the dielectric film are removed by the chemical mechanical polishing to form the interconnect. In the current damascenel method, since the copper easily reacts with the SiO₂ and diffuses during the formation of the interlayer dielectric film after the damascenel interconnect formation, a cap dielectric film made of SiN for the copper having a thickness of about 50 to 100 nm is formed by the plasma CVD using the SiH₄, NH₃ and N₂. Thereafter, the interlayer dielectric film made of SiO₂ is formed.

As shown in FIGS. 1A to 1E, a conventional plasma SiN film is formed in a CVD apparatus which may include a gas supply system, a plasma power source and a discharge device. At first, a silicon substrate 15 having copper is disposed on lift pins 14 in a deposition chamber 11 (FIG. 1A). Then, the lift pins 14 are descended to place the silicon wafer on a susceptor 12, and the silicon wafer 15 is heated to a specified temperature by a heater 13. Simultaneously, NH₃ and N₂ are introduced thereto through a gas pipe 17 for stabilizing the pressure therein (FIG. 1B). SiH₄ is introduced thereto and the SiN film formation is initiated by applying a radio-frequency (RF) power by the RF plasma source 16 (FIG. 1C). Then, the deposition chamber 11 is evacuated (FIG. 1D), and the silicon wafer is taken out from the chamber (FIG. 1E). In order to increase the adhesion strength between the copper and the SiN film, a pretreatment by using the plasma of NH₃ and N₂ may be conducted by applying the RF power after the pressure is stabilized.

However, the conventional technique includes the following problems.

(1) When the SiN film is formed without further treatment, the adhesion strength between the SiN and the copper is reduced to generate the peeling-off of the film by the copper oxide layer at the interface because the copper surface is oxidized. Accordingly, the removal of the oxide layer of the copper surface is required.

(2) When the pretreatment of the removal of the oxide layer and the deposition of the SiN film are conducted in the same deposition chamber at the substrate temperature of about 400° C., the copper easily agglomerates to deteriorate the surface morphology because the surface migration likely occurs due to the temperature rise of the wafer exposed to the plasma in the pretreatment and the removal of the oxide layer from the copper surface. The pretreatment which suppresses the agglomeration of the copper must be established.

(3) Methods for suppressing the copper agglomeration during the pretreatment include one for lowering the pretreatment temperature. When, however, the pretreatment temperature is lowered with the lowering of the deposition temperature, the film quality of the SiN is deteriorated.

### SUMMARY OF THE INVENTION

In view of the foregoing, an object of the present invention is to provide a method and an apparatus for forming a semiconductor device in which an interlayer dielectric film has an excellent adhesion to copper interconnect and the agglomeration of the copper is suppressed.

The present invention provides, in a first aspect thereof, a method for fabricating a semiconductor device including the steps of: forming an interconnect made of copper overlying a substrate; conducting a pretreatment of the copper in a deposition chamber at a specified temperature, desirably 300° C. or less; and forming a dielectric film on the copper by a chemical vapor deposition method in the a deposition chamber at a temperature higher than the specified temperature.

The present invention provides, in a second aspect thereof, an apparatus for fabricating a semiconductor device including: a deposition chamber for receiving a wafer having a copper interconnect layer thereon; a mechanism for conducting a pretreatment on the wafer at a specified temperature; and a mechanism for depositing a dielectric film on the copper interconnect layer at a temperature higher than the specified temperature.

In accordance with the first and second aspects of the present invention, the adhesion between the copper and the dielectric film, for example, made of SiN is improved by conducting the pretreatment of the SiN film for reducing an oxide layer of the copper surface, and the agglomeration of the copper can be prevented by the pretreatment.

The above and other objects, features and advantages of the present invention will be more apparent from the following description.

### BRIEF DESCRIPTION OF DRAWINGS

FIGS. 1A to 1E are schematic views sequentially showing a series of steps of conventionally fabricating a semiconductor device.

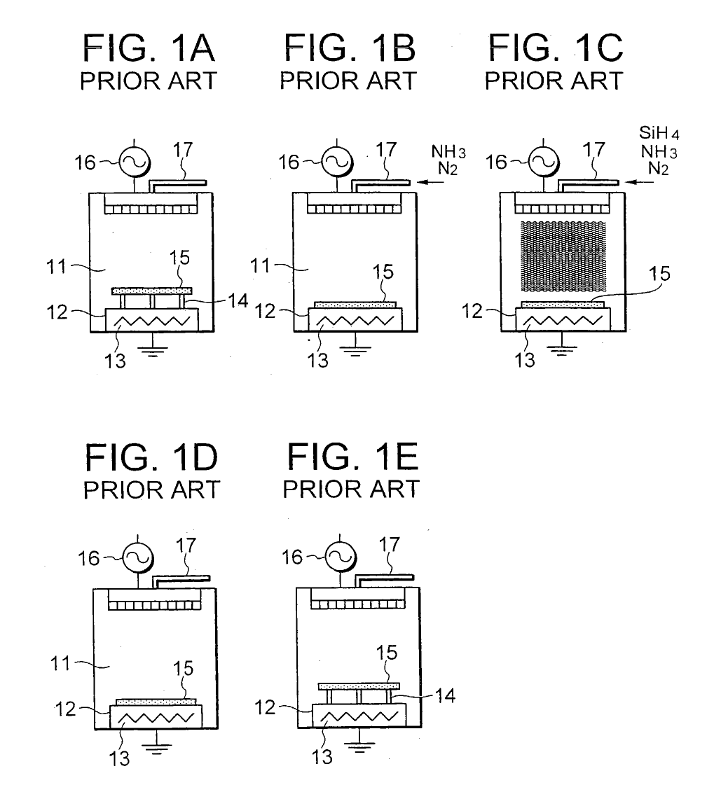

FIGS. 2A to 2G are schematic views sequentially showing a series of steps of fabricating a semiconductor device in a first embodiment.

FIGS. 3A to 3F are schematic views sequentially showing a series of steps of fabricating a semiconductor device in a second embodiment.

### PREFERRED EMBODIMENTS OF THE INVENTION

Now, the present invention is more specifically described with reference to accompanying drawings.

First Embodiment

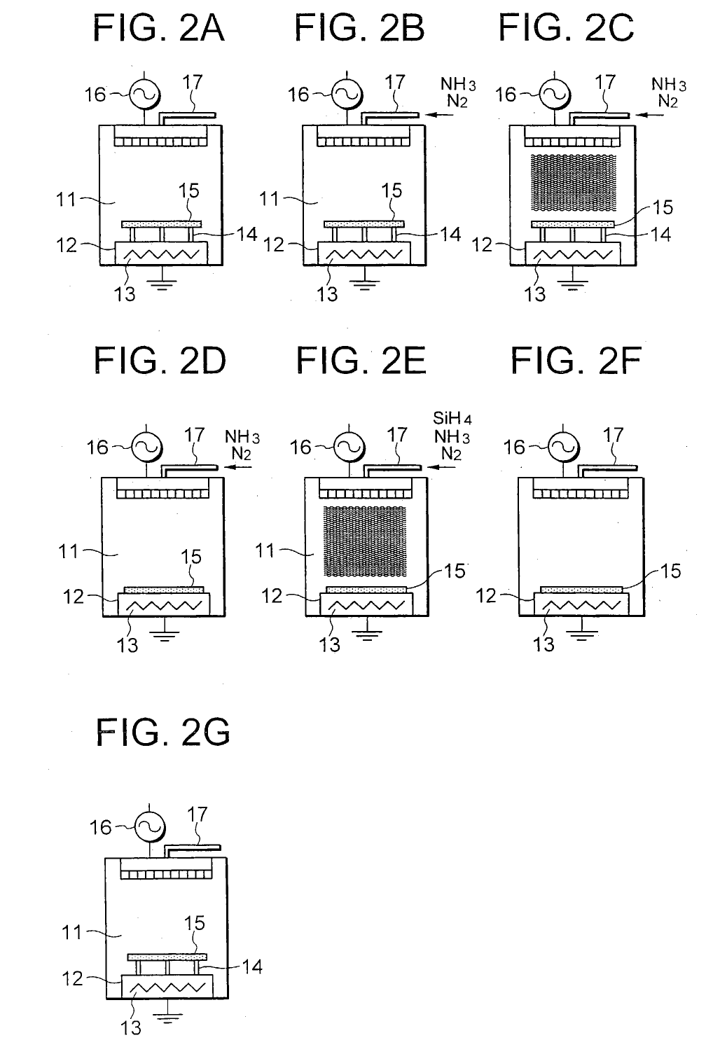

In a first embodiment, a SiN film was formed in accordance with procedures sequentially shown in FIGS. 2A to 2G.

At first, a silicon substrate 15 having an interconnect with copper-filled trenches was disposed on lift pins 14 in a deposition chamber 11 (FIG. 2A). A mixed gas including NH₃ (100 sccm) and N₂ (1000 sccm) was introduced to the deposition chamber 11 through a gas pipe 17 to maintain the inner pressure of the deposition chamber 11 to be about 5 Torr. (FIG. 2B). The surface oxide layer of the copper interconnect formed on the silicon substrate was reduced and removed by applying 100 W of the RF power having 13.56 MHz for 10 seconds from a RF plasma source 16 in a pretreatment (FIG. 2C). Then, the lift pins 14 were descended to place the silicon wafer on a susceptor 12 which had been heated to 400° C. by a heater 13 (FIG. 2D). After, for forming a SiN film, SiH₄ (100 sccm) was introduced to keep the inner pressure at 3 Torr., 500 W of a RF power was applied to form the SiN film having a thickness of 50 nm (FIG. 2E). After the deposition chamber was vacuumed (FIG. 2F), the lift pins were ascended to take out the silicon wafer (FIG. 2G). In this manner, the silicon wafer is not heated during the pretreatment by placing the silicon wafer on the susceptor 12 after the pretreatment. Accordingly, the agglomeration of the copper can be suppressed.

Although the NH₃ and the N₂ were used in the pretreatment of the first embodiment, only H₂, only the NH₃ or a mixed gas of N₂, H₂ and NH₃ may be used in place thereof. A plasma source for performing the plasma pretreatment may be disposed separately from that for forming the SiN film formation. Although the SiN is used as the CVD dielectric film in the embodiment, another dielectric film may be used which does not react with the copper in SiC, SiCN and an organic film having a low dielectric constant and functions for preventing the diffusion of the copper.

Second Embodiment

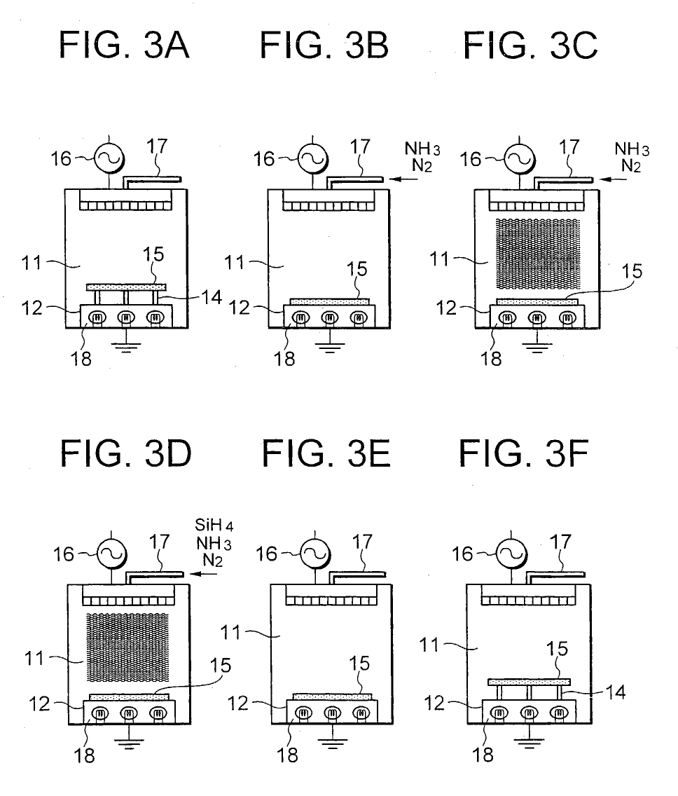

In a second embodiment, a SiN film was formed in accordance with procedures sequentially shown in FIGS. 3A to 2F.

In the embodiment, lamps 18 were used for rapidly heating a silicon wafer 15. At first, the silicon wafer 15 was disposed on lift pins 14 in a deposition chamber 11 (FIG. 3A). Then, the lift pins 14 were descended to place the silicon wafer on a susceptor 12. At this stage, the heating by the lamps 18 were not started. Then, the silicon wafer 15 was heated to 200° C. by the lamps 18, and a plasma pretreatment was conducted similarly to that of the first embodiment (FIG. 3C). Further, the silicon wafer 15 was heated to 400° C. to start film-formation of SiN (FIG. 3D). After the deposition chamber 11 was vacuumed (FIG. 3E), the lift pins were ascended to take out the silicon wafer (FIG. 3F). Although the pretreatment was conducted at 200° C., the pretreatment may be conducted at 300° C. or less to suppress the agglomeration of the copper. In place of the plasma pretreatment of the embodiment, the thermal pretreatment in a reduced gas atmosphere such as in NH₃ and N₂ may be conducted.

Since the above embodiments are described only for examples, the present invention is not limited to the above embodiments and various modifications or alternations can be easily made therefrom by those skilled in the art without departing from the scope of the present invention.

What is claimed:

1. A method of capping a copper interconnect in a semiconductor device, the method comprising the steps of:
placing the semiconductor device in a deposition chamber over and spaced from an susceptor therein;
introducing a gas containing hydrogen into the deposition chamber to achieve a first pressure in the deposition chamber;
removing a surface oxide from the copper interconnect by introducing RF power into the deposition chamber while the gas containing hydrogen is present and without heating the semiconductor device, and stopping the RF power after a first time period;
after the first time period, heating the susceptor to about 400° C. and lowering the semiconductor device onto the heated susceptor; and
while the semiconductor device is heated, introducing SiH₄ and RF power into the deposition chamber to form a SiN cap on the copper interconnect.

2. The method of claim 1, wherein the gas containing hydrogen includes NH₃ and N₂.

3. The method of claim 1, wherein the first time period is about 10 seconds.

4. The method of claim 1, wherein the surface oxide is removed by introducing 100 W of RF power at plural megahertz for about 10 seconds.

5. The method of claim 4, wherein the RF power is at 13-14 MHZ.

6. The method of claim 1, wherein the first pressure is about 5 Torr.

7. The method of claim 1, after the SiN cap has been formed, further comprising the step of elevating the semiconductor device above the susceptor and removing the semiconductor device.
